(19) United States
(12) Patent Application Publication
(10) Pub. No.: US 2014/0111705 A1
(43) Pub. Date: Apr. 24, 2014

(54) ELECTRONIC DISPLAY APPARATUS WITH A DEPLOYABLE HANDLE

(71) Applicants: Jason Wade, San Diego, CA (US); Robert Huntress, Carlsbad, CA (US)

(72) Inventors: Jason Wade, San Diego, CA (US); Robert Huntress, Carlsbad, CA (US)

(21) Appl. No.: 13/659,759

(22) Filed: Oct. 24, 2012

(51) Int. Cl. H05K 5/02; H04N 5/64

(52) U.S. Cl. CPC H05K 5/023; H04N 5/64
USPC 348/838; 361/809

(57) ABSTRACT

An electronic display apparatus with deployable handles is provided. Portion(s) of the electronic display apparatus may be lifted to form handles. The deployable handles may be configured to form an even and smooth surface of the electronic display apparatus when not in use. When needed, the deployable handles can be rotated (e.g., deployed) to function as handles.

### TECHNICAL FIELD

The present invention relates generally to display devices, and more particularly, various embodiments relate to electronic display devices having one or more deployable handles.

### DESCRIPTION OF THE RELATED ART

Electronic displays are popular and vastly used in many ways. Some are used in or with devices such as personal computers, smart phones, tablet computers, TVs, and other fixed or portable devices. Electronic displays might also be used in different ways for different industries, e.g., advertising billboards, onboard entertainment, conference centers. Those used in vehicles, ships, aircraft or other conveyances are often rack mountable. Such display devices often include permanent, fixed handles to aid in transportation, mounting and dismounting of the display device. While useful for transportation and mounting, these permanent handles are unnecessary for, and may interfere with, normal operation of the electronic display in situ. Electronic displays with permanent handles are less space effective due to the constant protrusion of the handles from the electronic displays. Further, permanent handles protruding from the display may interfere with the ergonomics of the installation and can cause injuries when people bump or fall into them. This holds particularly true when handles permanently protruding from the display are used in a moving vehicle or other active environment.

### BRIEF SUMMARY OF EMBODIMENTS OF THE INVENTION

According to various embodiments of the devices and methods described herein, dedicated and fixed handles may be eliminated and replaced with pivoting, collapsing, articulating, retracting or otherwise deployable handles. In some embodiments, the electronic display apparatus includes a frame that is constructed such that without the use of tools, portion(s) of the frame can be deployed to form and be used as handle(s), and can be returned to a stowed position when no longer in use.

According to embodiments of the invention, an electronic display apparatus comprises a video display element that has a viewable region and a housing that frames the video display element. In various embodiments, a first portion of the housing is configured such that a surface of the first portion of the housing faces at least partially or substantially in a same direction as the viewable region, and the first portion of the housing comprises a recess. The housing may further comprise a second portion that is coupled to the first portion and has an outer surface, where the second portion is configured to have a first position (also referred herein as a closed position) where the second portion is disposed in the recess and the outer surface of the second portion is substantially flush with the surface of the first portion. The second portion may be further configured to have a second position (also referred herein as an open position) where the second portion protrudes from the surface of the first portion. When protruding from the given surface, the second portion may function as a handle, useful for transporting, mounting, or dismounting the electronic display.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIG. 1A is a diagram depicting an exemplary electronic display device with deployable handles in an open position in accordance with an embodiment of the apparatus described herein.

FIG. 1B is a diagram depicting an exemplary electronic display device with deployable handles in a closed position in accordance with an embodiment of the apparatus described herein.

### DETAILED DESCRIPTION OF THE EMBODIMENTS OF THE INVENTION

The present invention is directed toward an electronic display apparatus having one or more deployable handles. In one embodiment, the electronic display apparatus comprises a frame that is constructed such that, without the use of tools, portion(s) of the frame can be lifted up to form handle(s). The handle(s) may be rotated away from the frame and subsequently returned to a stowed position when the handle(s) are no longer in use.

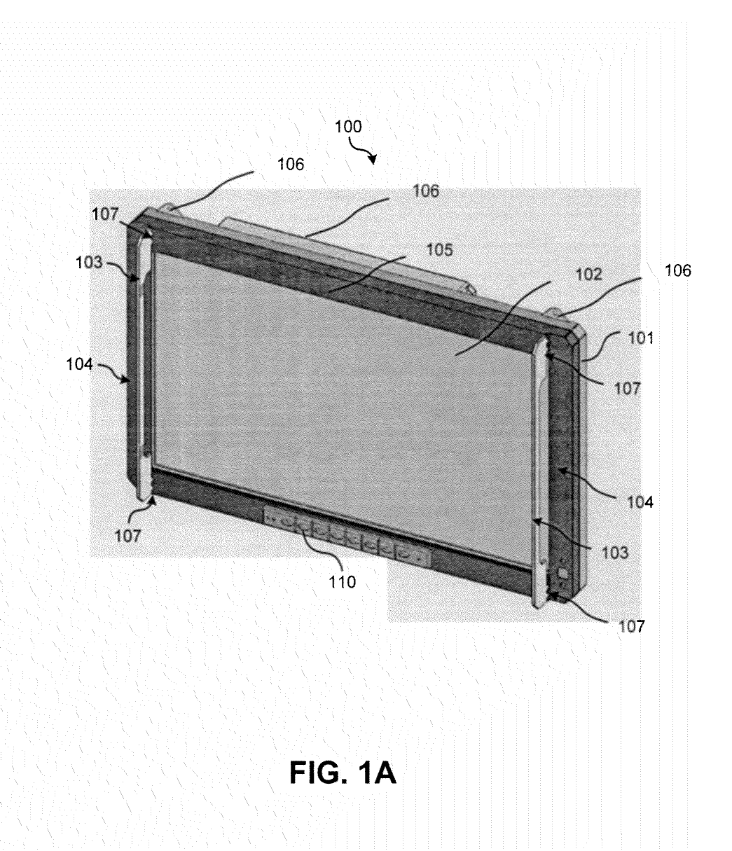

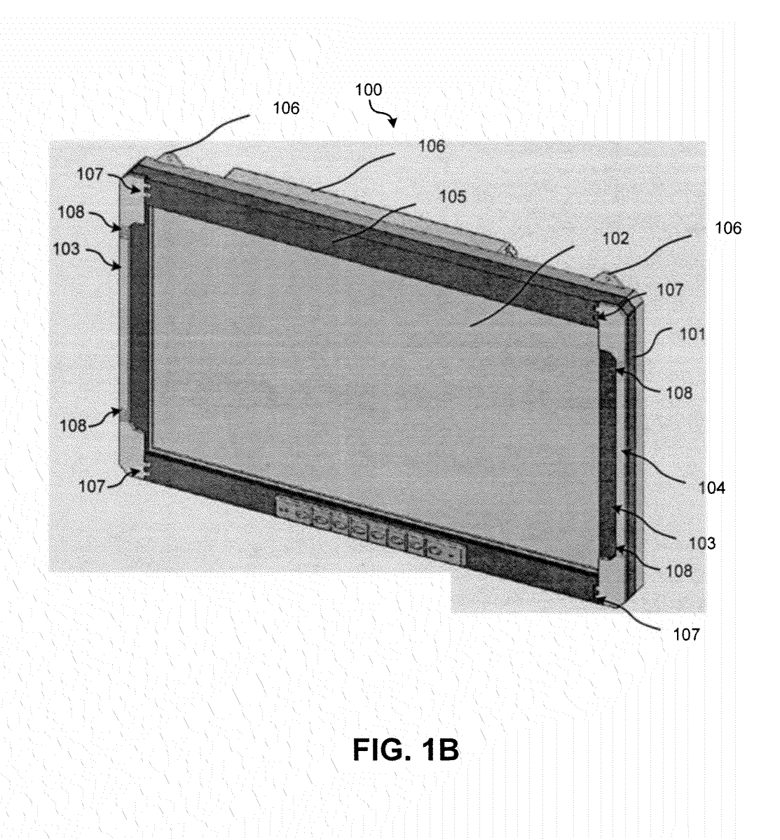

FIG. 1A is a diagram depicting an exemplary electronic display device 100 with deployable handles 103, in an open position in accordance with an embodiment. In various embodiments, the electronic display device 100 comprises a frame having two portions—a fixed portion 101 and a deployable portion 103 configured to function as a handle when deployed (hereinafter referred as “handle 103”). According to one embodiment, the electronic display device 100 is rectangular and has two deployable handles 103. As shown, the two deployable handles 103 may be disposed on each side of the electronic display device 100. The deployable handles 103 can be disposed on the left and right sides of the electronic display, or on the top and bottom edges of the electronic display. Other locations on the electronic display may be suitable as well. After reading this description, one of ordinary skill in the art will appreciate that an electronic display device may be in other shapes, may have various numbers of deployable handles, and the deployable handles may be disposed on the electronic display device differently.

The electronic display device 100 in FIG. 1A comprises a fixed frame portion 101, a display section 102, one or more deployable handles 103, a surface 105, mounting fixtures 106, and a set of user input mechanisms 110. The display section 102 (also referred to herein as the “viewable region”) displays video or other visual content output to the electron display device 100. The display section 102 may comprise any of a number of display types, including, for example, a light-emitting diode (LED) display, an organic LED display (OLED), a liquid crystal display (LCD), a plasma display, or a cathode ray tube (CRT) display. Also, display section 102 might be implemented with a touch screen display or conventional display technology. Although particular exemplary displays are described herein, after reading this description, one of ordinary skill in the art will understand that the apparatuses described herein can be used with or implemented into other display devices using alternative display technologies. Moreover, in further embodiments, the apparatuses described herein can be used with various other types of equipment, including, for instance, electronic equipment, test equipment, rack-mounted equipment and the like.

In the illustrated example, the fixed frame portion 101 is disposed around the circumference of the display section 102. The fixed frame portion 101 may be provided to impart strength to the display device and to provide the ability to mount the display device 100 to a mounting structure (e.g., an in-vehicle rack). Additionally, the electronic display device 100 may include one or more mounting fixtures 106 that enable the electronic display device 100 to be mounted to a surface, such as, for example, a wall, a console, an equipment rack or other structure. For some embodiments, the mounting fixtures 106 may be an integral part of the fixed portion of the frame 101. In some embodiments, the mounting fixtures 106 may be separate components that can be attached (e.g., removably attached) to the display device 100.

The electronic display device 100 may comprise the set of user input mechanisms 110 comprising, for example, a button, a keypad, switches, dials, or the like. This may be in addition to, or in place of, a touch-screen user interface (UI) presented on the display section 102 of the electronic display device 101. The set of input mechanisms 110 may be configured to allow a user to interact with and/or control the electronic display device 100. In some instances, the set of input mechanisms may be used to control how a video is displayed on the display section 102, to select a program, or to adjust the color, brightness and contrast of the electronic display device 100.

The fixed frame portion 101 may define a surface 105 to which the deployable handles 103 are coupled. Additionally, the surface 105 and the display section 102 may face the same direction or substantially the same direction. In some embodiments, some or all of the surface 105 may lie in one or more planes that are not substantially parallel to the plane of display section 102.

In various embodiments, the electronic display device 100 may comprise a set of hinges 107. The set of hinges 107 may be used to couple the deployable handles 103 to the fixed frame portion 101 such that at least a part of the deployable handles may be lifted and rotated away from the fixed frame portion 101, and be retracted in an articulating fashion. The set of hinges 107 may be disposed in locations as appropriate to allow deployment and retraction of handles 103. For example, in the illustrated example, the set of hinges 107 are disposed toward the top and bottom of the right and left sides of the frame 101. The deployable handles 103 may be configured to rotate about an axis of the set of hinges 107 so that the deployable handles 103 pivot away from the surface 105 for deployment and return to the closed position after use. In one embodiment, the deployable handles 103 may rotate anywhere from 0-150 degrees around the axis of the set of hinges 107. Other degrees of freedom may be provided depending on the size and shape of the deployable handles 103, the size and shape of the fixed frame portion 101, or the intended application. In various embodiments, the deployable handles 103 may rotate to a position that is least approximately perpendicular to the frame surface 105, such as to allow the deployable handles 103 to be positioned for ergonomic use when deployed.

Also, for some embodiments, the set of hinges 107 may be implemented with friction sufficient to cause the deployable handles 103 to remain in a set position when deployed. In some embodiments, the set of hinges 107 may be implemented with lesser amount of friction such that the deployable handles 103 may move with ease. Sprung hinges may be utilized to cause the deployable handles 103 to spring back to a default position (e.g., the closed position) when released from a non-default position (e.g., the open position). For instance, springs or similar mechanisms may be included to allow the hinges to pivot back to a retracted/closed position when released from a deployed/open position. In various embodiments, the friction of the set of hinges 107 may permit the deployable handles 103 to remain at any position relative to the surface 105. Notches or detents may be used to allow the deployable handles 103 to more readily remain in a desired position, even in embodiments where low friction or spring mechanisms are used.

The set of hinges 107 may be implemented using any of a number of different types of hinges. The set of hinges 107 may, for example, be concealed (e.g., as a concealed butterfly hinge or flush hinge), or visible. In some embodiments, a given hinge in the set of hinges 107 is not a separate component, but rather may comprise components that are integral to either the deployable handles 103 or the fixed portion 101, or both. For example, as shown in the embodiment of FIGS. 1A and 1B, the set of hinges 107 comprises a pivot hinge and the deployable handles 103 include protruding members that are complementary to similar members of the fixed frame portion 101. Together, the members may define a pivot point (e.g., a barrel and pin arrangement) about which the deployable handles 103 can rotate.

The deployable handles 103 may have a deployed/open position, as illustrated in FIG. 1A, and a retracted/closed position, as illustrated in FIG. 1B. With continued reference to FIG. 1A, the surface 105 may comprise recesses 104 as shown. The recesses 104 may be configured to accommodate the deployable handles 103 such that when the deployable handles 103 are in the retracted/closed position, the deployable handles 103 are at least substantially flush with the surface 105. In other words, when the deployable handles 103 are in the closed position, the surface 105 of the fixed frame portion 101 may be approximately or substantially planar with the top surfaces of the deployable handles 103. One of ordinary skill in the art should understand that other configurations of recesses may be used to allow the deployable handles 103 to be retracted into the fixed frame portion 101 with little or no protrusion.

As illustrated in FIG. 1A, the deployable handles 103 are roughly perpendicular to the fixed frame portion 101 when in the fully deployed position. Stops may be provided such that deployable handles 103 do not move beyond a predetermined degree of rotation. Additionally, notches or other detents may be used to retain the deployable handles 103 in one or more desired deployed positions. Although not illustrated, locking mechanisms may be included to lock the deployable handles 103 in place in a deployed position. In such an embodiment, the deployable handles 103, when deployed, may function as handles or be used for other purposes such as a handhold or a grab bar. Users may prefer to keep these deployable handles in their open positions when the electronic display device 100 is used in a moving environment, for example, in a vehicle, a ship, or an airplane, so that users may rely on these handles for safety reasons.

FIG. 1B is a diagram depicting the example electronic display device 100 of FIG. 1A, but with the deployable handles 103 in a closed position. The deployable handles 103, when in the closed position, may be disposed in the recesses 104 of the fixed frame portion 101. In one embodiment, when in the closed position, the deployable handles 103 may be substantially flush with the surface 105. The fixed frame portion 101, the deployable handles 103, and the set of hinges 107 may be constructed to fit together snugly to form an even and smooth surface of the electronic display device 100. In various embodiments, the deployable handles 103 may be locked into the closed position snugly against the recesses 104.

In the illustrated example, ridges, furrows, grooves or other striations may be included on one or more surfaces of the deployable handles 103 to provide a grip surface. This may allow a user to obtain a better grip on the deployable handles 103 to pull them to a deployed position. In some embodiments, the deployable handles 103 and the set of hinges 107 may be configured such that the handles 103 must be pulled outward (to the left and right) before the deployable handles 103 can be lifted. In such embodiments, spring mechanisms may be used to keep the deployable handles 103 in place and provide some resistance to pulling the deployable handles 103 to a deployable stance.

In various embodiments, the fixed frame portion 101 and the deployable handles 103 may be constructed of lightweight, aircraft grade, Computer Numerical Control (CNC) machined aluminum. In some embodiments, polycarbonates, steel or other materials may be used. After reading this description, one of ordinary skill in the art will appreciate that other materials may also be used in the construction of various embodiments.

While various embodiments of the present invention have been described above, it should be understood that they have been presented by way of example only, and not of limitation. Likewise, the various diagrams may depict an exemplary construction or other configuration for some embodiments, which is done to aid in understanding the features and functionality that can be included. Various embodiments are not restricted to the illustrated exemplary constructions or configurations. Indeed, it will be apparent to one of skill in the art how alternative functional or physical configurations can be implemented to carry out the desired features of embodiments.

Although several embodiments are described above, it should be understood that the various features, aspects and functionality described in one or more individual embodiments are not limited in their applicability to the respective particular embodiment with which they are described. Rather, these features, aspects and functionality, either alone or in various combinations, may be applied to one or more of the other embodiments, whether or not such embodiments are described and whether or not such features are presented as being a part of a described embodiment. Thus, the breadth and scope of embodiments should not be limited by any of the above-described embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. Additionally, the various embodiments set forth herein are described in terms of exemplary illustrations. As will become apparent to one of ordinary skill in the art after reading this document, the illustrated embodiments and their various alternatives can be implemented without confinement to the illustrated examples.

What is claimed is:

1. An electronic display apparatus, comprising:
a video display element having a viewable region;
a first portion of a housing framing the video display element such that a surface of the first portion of the housing faces at least substantially in a same direction as the viewable region, the first portion of the housing further comprising a recess; and
a second portion of the housing coupled to the first portion and having an outer surface, wherein the second portion is configured to have a first position in which the second portion is disposed in the recess and its outer surface is substantially flush with the surface of the first portion, and a second position where the second portion protrudes from the surface such as to function as a handle of the electronic display apparatus.

2. The electronic display apparatus of claim 1 further comprising a set of hinges, wherein the set of hinges couples the first portion to the second portion.

3. The electronic display apparatus of claim 2, wherein the second portion rotates about the set of hinges and interchanges from the first position to the second position.

4. The electronic display apparatus of claim 2, wherein the set of hinges are inlayed in the surface of the first portion.

5. The electronic display apparatus of claim 1, wherein the second portion is perpendicular to the surface in the second position.

6. The electronic display apparatus of claim 1, wherein the second portion is lockable in the first position.

7. The electronic display apparatus of claim 6, wherein the second portion is configured to unlock from the first position and to deploy to the second position.

8. The electronic display apparatus of claim 1, wherein the second portion is lockable in the second position.

9. The electronic display apparatus of claim 8, wherein the second portion is configured to unlock from the second position and to return to the first position.

10. The electronic display apparatus of claim 1, further comprising a mounting fixture.

11. The electronic display apparatus of claim 1, wherein the viewable region is a touchscreen.

12. A frame coupled to an electronic device, comprising:
a first portion comprising a recess, wherein the first portion frames the electronic device; and
a second portion coupled to the first portion and having an outer surface, wherein the second portion is configured to have a first position in which the second portion is disposed in the recess and its outer surface is substantially flush with a surface of the first portion, and a second position where the second portion protrudes from the surface such as to function as a handle of the electronic display device.

13. The frame of claim 12 further comprising a set of hinges, wherein the set of hinges couples the first portion to the second portion.

14. The frame of claim 13, wherein the second portion rotates about the set of hinges and interchanges from the first position to the second position.

15. The frame of claim 13, wherein the set of hinges are inlayed in the surface of the first portion.

16. The frame of claim 12, wherein the second portion is perpendicular to the surface in the second position.

17. The frame of claim 12, wherein the second portion is lockable in the first position.

18. The frame of claim 17, wherein the second portion is configured to unlock from the first position and to deploy to the second position.

19. The frame of claim 12, wherein the second portion is lockable in the second position.

20. The frame of claim 18, wherein the second portion is configured to unlock from the second position and to return to the first position.
